(19) United States
(12) Patent Application Publication
(10) Pub. No.: US 2018/0072947 A1
(43) Pub. Date: Mar. 15, 2018

(54) Solution-Phase Synthesis of Layered Transition Metal Dichalcogenide Nanoparticles

(71) Applicant: Nanoco Technologies Ltd., Manchester (GB)

(72) Inventors: Nigel Pickett, Manchester (GB); Ombretta Masala, Manchester (GB)

(21) Appl. No.: 15/698,835

(22) Filed: Sep. 8, 2017

Related U.S. Application Data
(60) Provisional application No. 62/393,387, filed on Sep. 12, 2016.

(51) Int. Cl. C09K 11/68; C09K 11/06; C30B 7/14; C30B 29/46; C30B 33/00

(52) U.S. Cl. CPC C09K 11/681; C09K 11/06; C30B 7/14; B82Y 40/00; C30B 33/00; C09K 2211/188; C09K 2211/1007; C30B 29/46

(57) ABSTRACT

A method of synthesizing two-dimensional (2D) nanoparticles of transition metal dichalcogenide (TMDC) material utilises a molecular cluster compound. The method allows a high degree of control over the shape, size and composition of the 2D TMDC nanoparticles, and may be used to produce material with uniform properties in large quantities.

### CROSS-REFERENCE TO RELATED APPLICATIONS

This application claims the benefit of U.S. Provisional Application Ser. No. 62/393,387 filed on Sep. 12, 2016, the contents of which are hereby incorporated by reference in their entirety.

### STATEMENT REGARDING FEDERALLY SPONSORED RESEARCH OR DEVELOPMENT

Not Applicable

### BACKGROUND OF THE INVENTION

### 1. Field of the Invention

The present invention generally relates to the synthesis of two-dimensional (2D) materials. More particularly, the invention relates to the solution-phase synthesis of layered transition metal dichalcogenide materials.

### 2. Description of the Related Art including information disclosed under 37 CFR 1.97 and 1.98.

The isolation of graphene via the mechanical exfoliation of graphite [K. S. Novoselov, A. K. Geim, S. V. Morozov, D. Jiang, Y. Zhang, S. V. Dubnos, I. V. Grigorieva and A. A. Firsov, Science, 2004, 306, 666] has sparked strong interest in two-dimensional (2D) layered materials. The properties of graphene include exceptional strength, and high electrical and thermal conductivity, while being lightweight, flexible and transparent. This opens up the possibility of a wide array of potential applications, including high speed transistors and sensors, barrier materials, solar cells, batteries, and composites.

Other classes of 2D materials of interest include transition metal dichalcogenide (TMDC) materials, hexagonal boron nitride (h-BN), as well as those based on Group 14 elements, such as silicene and germanene. The properties of these materials can range from semi-metallic, for example, NiTe₂ and VSe₂, to semiconducting, for example, WSe₂ and MoS₂, to insulating, for example, h-BN.

2D nanosheets of TMDC materials are of increasing interest for applications ranging from catalysis to sensing, energy storage and optoelectronic devices. Mono- and few-layered TMDCs are direct band gap semiconductors, with variation in band gap and carrier type (n- or p-type) depending on composition, structure and dimensionality.

Of the 2D TMDCs, the semiconductors WSe₂ and MoS₂ are of particular interest because, while largely preserving their bulk properties, additional properties arise due to quantum confinement effects when the thickness of the materials is reduced to mono- or few layers. In the case of WSe₂ and MoS₂, these include the exhibition of an indirect-to-direct band gap transition, with strong excitonic effects, when the thickness is reduced to a monolayer. This leads to a strong enhancement in photoluminescence efficiency, opening up new opportunities for the application of such materials in optoelectronic devices. Other materials of interest include WS₂ and MoSe₂.

Group 4 to 7 TMDCs predominantly crystallise in layered structures, leading to anisotropy in their electrical, chemical, mechanical and thermal properties. Each layer comprises a hexagonally packed layer of metal atoms sandwiched between two layers of chalcogen atoms via covalent bonds. Neighbouring layers are weakly bound by van der Waals interactions, which may easily be broken by mechanical or chemical methods to create mono- and few-layer structures.

For high-performance applications, flat, defect-free material is required, whereas for applications in batteries and supercapacitors, defects, voids and cavities are desirable.

Mono- and few-layer TMDC materials may be produced using “top-down” and “bottom-up” approaches. Top-down approaches involve the removal of layers, either mechanically or chemically, from the bulk material. Such techniques include mechanical exfoliation, ultrasound-assisted liquid phase exfoliation (LPE), and intercalation techniques. Bottom-up approaches, wherein layers are grown from their constituent elements, include chemical vapour deposition (CVD), atomic layer deposition (ALD), and molecular beam epitaxy (MBE), as well as solution-based approaches including hot-injection methods.

Monolayer and few-layer sheets of TMDC materials can be produced in small quantities via the mechanical peeling of layers of the bulk solid (the so-called the “Scotch tape method”) to produce uncharged sheets that interact through van der Waals forces only. Mechanical exfoliation may be used to yield highly crystalline layers on the order of millimetres, with size being limited by the single crystal grains of the starting material. However, the technique is low-yielding, unscalable and provides poor thickness control. Since the technique produces flakes of different sizes and thicknesses, optical identification must be used to locate the desired atomically thin flakes. As such, the technique is best suited to the production of TMDC flakes for the demonstration of high-performance devices and condensed matter phenomena.

TMDC materials may be exfoliated in liquids by exploiting ultrasound to extract single layers. The LPE process usually involves three steps: i) dispersion of bulk material in a solvent; ii) exfoliation; and, iii) purification. The purification step is necessary to separate the exfoliated flakes from the un-exfoliated flakes and usually requires ultracentrifugation. Ultrasound-assisted exfoliation is controlled by the formation, growth and implosive collapse of bubbles or voids in liquids due to pressure fluctuations. Sonication is used to disrupt the weak van der Waals forces between sheets to create few- and single-layer 2D flakes from bulk material. Despite the advantages offered by LPE in terms of scalability, challenges of the process include thickness control, poor reaction yields, and the production being limited to small flakes.

Top-down methods can be used to produce high quality TMDC monolayers at low cost, and are convenient for fundamental research for the realisation of proof-of-concept devices. However, using these methods it is difficult to achieve good lateral dimensions, uniformity and scalability over large area substrates. As such, there is great interest in the development of bottom-up methods, starting from the constituent elements of the TMDC material, to synthesise large quantities of high quality monolayers, either free-standing or on a substrate.

Large area scalability, uniformity and thickness control are routinely achieved for TMDC materials using CVD. However, drawbacks include difficulty in maintaining uniform growth and wastefulness due to large amounts of unreacted precursors.

Solution-based approaches to the formation of TMDC flakes are highly desirable, as they may offer control over the size, shape and uniformity of the resulting materials, as well as enabling ligands to be applied to the surface of the materials to provide solubility and, thus, solution processability. The application of organic ligands to the surface of the materials may also limit the degradation, as observed for CVD-grown samples, by acting as a barrier to oxygen and other foreign species. The resulting materials are free-standing, further facilitating their processability. However, the solution-based methods thus far developed do not provide a scalable reaction to generate TMDC layered materials with the desired crystallographic phase, tunable narrow shape and size distributions and a volatile capping ligand, which is desirable so that it may be easily removed during device processing.

One of the challenges in the production of TMDC layered materials is to achieve compositional uniformity, whether high-quality, defect-free or defect-containing material is required, on a large scale. Further challenges include forming TMDC flakes with a homogeneous shape and size distribution.

Thus, there is a need for a bottom-up synthesis method that produces uniform TMDC materials in high yield.

### BRIEF SUMMARY OF THE INVENTION

Herein, a solution-phase synthesis of layered 2D TMDC nanoparticles is described. The method is based on a “molecular seeding” approach, whereby synthesis of the layered TMDC nanoparticle material employs a molecular cluster as a template to initiate growth from other precursors present in the reaction solution.

In one embodiment, the molecular cluster contains the elements required in the subsequent nanoparticles. In another embodiment, the molecular cluster contains one of the elements required in the subsequent nanoparticles. In a further embodiment, the molecular cluster contains none of the elements required in the subsequent nanoparticles.

In one embodiment, the molecular cluster is pre-fabricated. In another embodiment, the molecular cluster is formed in situ.

In one embodiment, the synthesis involves the conversion of a first precursor and a second precursor to nanoparticle material in the presence of a molecular cluster.

In one embodiment, the synthesis involves the conversion of a single-source precursor to nanoparticle material in the presence of a molecular cluster.

During the reaction, “molecular feedstocks”, i.e. further precursors, may be added to sustain nanoparticle growth and to inhibit Ostwald ripening and defocussing of the nanoparticle size range. The molecular feedstock may be added as a gas, a liquid, a solution, a slurry, or a solid.

Nanoparticle growth may be initiated through heating (thermolysis) or via solvothermal methods. Synthesis may also include changing the reaction conditions, such as pH, pressure, or using microwave or other electromagnetic radiation.

Once the desired particle size is reached, further particle growth may be inhibited by changing the reaction conditions, for example, lowering the temperature.

Examples of suitable nanoparticle materials that may be formed include, but are not restricted to, MoS₂, MoSe₂, WS₂ or WSe₂, and doped materials and alloys thereof.

In some embodiments, the nanoparticles are capped with one or more organic ligands.

Methods according to the invention are scalable and facilitate the formation of nanoparticles with uniform properties in large quantities.

In some embodiments, the nanoparticles may be cut to form, for example, 2D nanoflakes.

### BRIEF DESCRIPTION OF THE DRAWING(S)

FIG. 1 is a Raman spectrum of MoS₂ nanoparticles prepared according to Example 1.

FIG. 2 is a photoluminescence spectrum of MoS₂ 2D quantum dots prepared according to Example 2, excited at different wavelengths.

### DETAILED DESCRIPTION OF THE INVENTION

Herein, a solution-phase synthesis of layered 2D TMDC nanoparticles is described. The method is based on a “molecular seeding” approach, whereby synthesis of the layered TMDC nanoparticle material employs a molecular cluster as a template to initiate growth from other precursors present in the reaction solution.

As used herein, the term “nanoparticle” is used to describe a particle with dimensions on the order of approximately 1 to 100 nm. The term “quantum dot” (QD) is used to describe a semiconductor nanoparticle displaying quantum confinement effects. The dimensions of QDs are typically, but not exclusively, between 1 to 10 nm. The terms “nanoparticle” and “quantum dot” are not intended to imply any restrictions on the shape of the particle. The term “2D nanoflake” is used to describe a particle with lateral dimensions on the order of approximately 1 to 100 nm and a thickness between 1 to 5 atomic or molecular monolayers.

As used herein, “molecular cluster” means a cluster of three of more metal or non-metal atoms and its associated ligands of sufficiently well-defined chemical structure such that all molecules of the cluster compound possess the same relative molecular mass. Thus, the molecular clusters are identical to one another in the same way that one H₂O molecule is identical to another H₂O molecule.

As used herein, “chalcogen” means an element of Group 16 of the periodic table.

In one embodiment, the molecular cluster contains the elements required in the subsequent nanoparticles. In another embodiment, the molecular cluster contains one of the elements required in the subsequent nanoparticles. In a further embodiment, the molecular cluster contains none of the elements required in the subsequent nanoparticles.

In one embodiment, the molecular cluster is formed in situ.

Some precursors may not be present at the beginning of the reaction process, but may be added as the reaction proceeds, for example as a gas, dropwise as a solution, as a liquid, a slurry or as a solid.

The synthesis involves the conversion of one of more precursors to nanoparticles in the presence of a molecular cluster.

Suitable transition metal precursors may include, but are not restricted to, inorganic precursors, for example:
metal halides such as WClₙ (n=4-6), Mo₆Cl₁₂, MoCl₃, [MoCl₅]₂, NiCl₂, MnCl₂, VCl₃, TaCl₅, RuCl₃, RhCl₃, PdCl₂, HfCl₄, NbCl₅, FeCl₂, FeCl₃, TiCl₄, SrCl₂, SrCl₂.6H₂O, WO₂Cl₂, MoO₂Cl₂, WF₆, MoF₆, NiF₂, MnF₂, TaF₅, NbF₅, FeF₂, FeF₃, TiF₃, TiF₄, SrF₂, NiBr₂, MnBr₂, VBr₃, TaBr₅, RuBr₃.XH₂O, RhBr₃, PdBr₂, HfBr₄, NbBr₅, FeBr₂, FeBr₃, TiBr₄, SrBr₂, NiI₂, MnI₂, RuI₃, RhI₃, PdI₂ or TiI₄;
(NH₄)₆H₂W₁₂O₄₀ or (NH₄)₆H₂Mo₁₂O₄₀;
organometallic precursors such as metal carbonyl salts, for example, Mo(CO)₆, W(CO)₆, Ni(CO)₄, Mn₂(CO)₁₀, Ru₃(CO)₁₂, Fe₃(CO)₁₂ or Fe(CO)₅ and their alkyl and aryl derivatives;
acetates, for example, Ni(ac)₂.4H₂O, Mn(ac)₂.4H₂O, Rh₂(ac)₄, Pd₃(ac)₆, Pd(ac)₂, Fe(ac)₂ or Sr(ac)₂, where ac=OOCCH₃;
acetylacetonates, for example, Ni(acac)₂, Mn(acac)₂, V(acac)₃, Ru(acac)₃, Rh(acac)₃, Pd(acac)₂, Hf(acac)₄, Fe(acac)₂, Fe(acac)₃, Sr(acac)₂ or Sr(acac)₂.2H₂O, where acac=CH₃C(O)CHC(O)CH₃;
hexanoates, for example, Mo[OOCH(C₂H₅)C₄H]ₓ, Ni[OOCCH(C₂H₅)C₄H₉]₂, Mn[OOCCH(C₂H₅)C₄H₉]₂, Nb[OOCCH(C₂H₅)C₄H₉]₄, Fe[OOCCH(C₂H₅)C₄H₉]₃ or Sr[OOCCH(C₂H₅)C₄H₉]₂;
stearates, for example, Ni(st)₂ or Fe(st)₂, where st=O₂Cl₁₈H₃₅;
amine precursors, for example, complexes of the form [M(CO)ₙ(amine)₆₋ₙ];
metal alkyl precursors, for example, W(CH₃)₆, or
bis(ethylbenzene)molybdenum [(C₂H₅)_{y}C₆H_{6-y}]₂Mo (y=1-4).

Suitable chalcogen precursors include, but are not restricted to, an alcohol, an alkyl thiol or an alkyl selenol; a carboxylic acid; H₂S or H₂Se; an organo-chalcogen compound, for example thiourea or selenourea; inorganic precursors, for example Na₂S, Na₂Se or Na₂Te; phosphine chalcogenides, for example trioctylphosphine sulphide, trioctylphosphine selenide or trioctylphosphine telluride; octadecene sulphide, octadecene selenide or octadecene telluride; or elemental sulphur, selenium or tellurium. Particularly suitable chalcogen precursors include linear alkyl selenols and thiols such as octane thiol, octane selenol, dodecane thiol or dodecane selenol, or branched alkyl selenols and thiols such as tert-dibutyl selenol or tert-nonyl mercaptan, which may act as both a chalcogen source and capping agent.

In one embodiment, the synthesis involves the conversion of a single-source precursor to nanoparticles in the presence of a molecular cluster. As used herein, a “single-source precursor” is a single molecule that contains all of the elements to be incorporated into the nanoparticles, which decomposes under the reaction conditions to form ions that react to form the nanoparticles. Examples of suitable single-source precursors include, but are not restricted to: alkyl dithiocarbamates; alkyl diselenocarbamates; complexes with thiuram, for example, WS₃L₂, MoS₃L₂ or MoL₄, where L=E₂CNR₂, E =S and/or Se, and R=methyl, ethyl, butyl and/or hexyl; (NH₂)₂MoS₄; (NH₂)₂WS₄; or Mo(S^{t}Bu)₄.

The molar ratio of the molecular cluster to the nanoparticle precursor(s) may vary from about 1:1 to about 1:100, for example from about 1:1 to about 1:20.

In one embodiment, the synthesis involves the conversion of a first precursor and a second precursor to nanoparticle material in the presence of a molecular cluster. The ratio of the first precursor to the second precursor may vary from about 1:0.05 to about 1:20, for example from about 1:0.1 to about 1:10.

The conversion of said precursor(s) to nanoparticle material takes place in one or more suitable reaction solvents. A person of ordinary skill in the art will recognise that the choice of solvent(s) is at least partly dependent on the nature of the reacting species, i.e. the precursor composition and/or the cluster compound and/or the type of nanoparticles to be formed. The reaction solvent may be a Lewis base-type coordinating solvent, for example, a phosphine such as trioctylphosphine (TOP), a phosphine oxide such as trioctylphosphine oxide (TOPO), or an amine such as hexadecylamine (HDA). Alternatively, the solvent may be a non-coordinating solvent, for example, an alkane, alkene, or a heat transfer fluid such as a heat transfer fluid comprising a hydrogenated terphenyl, for example THERMINOL® 66 [SOLUTIA INC., 575 MARYVILLE CENTRE DRIVE, ST. LOUIS, Mo. 63141]. If a non-coordinating solvent is used, the reaction may proceed in the presence of a further coordinating agent to act as a ligand or capping agent. Capping agents are typically Lewis bases, for example phosphines, phosphine oxides, and/or amines, but other agents are available such as oleic acid or organic polymers, which form protective sheaths around the nanoparticles. Other suitable capping agents include alkyl thiols or selenols, include linear alkyl selenols and thiols such as octane thiol, octane selenol, dodecane thiol or dodecane selenol, or branched alkyl selenols and thiols such as tert-dibutyl selenol or tert-nonyl mercaptan, which may act as both a chalcogen source and capping agent. Further suitable ligands include bidentate ligands that may coordinate the surface of the nanoparticles with groups of different functionality, for example, S⁻ and O⁻ end groups.

The temperature of the reaction solvent(s) needs to be sufficiently high to ensure satisfactory dissolution and mixing of the cluster, but is preferably sufficiently low to prevent disruption of the integrity of the cluster compound molecules.

During the reaction, “molecular feedstocks”, i.e. further precursors, may be added to sustain nanoparticle growth and to inhibit Ostwald ripening and defocussing of the nanoparticle size range. The molecular feedstock may be added as a gas, a liquid, a solution, a slurry, or a solid.

Nanoparticle growth may be initiated through heating (thermolysis) or via solvothermal methods. Synthesis may also include changing the reaction conditions, such as pH, pressure, or using microwave or other electromagnetic radiation.

Once the desired particle size is reached, further particle growth may be inhibited by changing the reaction conditions, for example, lowering the temperature. In one embodiment, an annealing step may be included to “size focus” the nanoparticles via Ostwald ripening.

The nanoparticles may subsequently be isolated from the reaction solution, for example, by centrifugation or filtration.

The molecular cluster may be pre-fabricated and added to the reaction solution at the beginning of the reaction, or may be formed in situ prior to nanoparticle growth.

Examples of suitable transition metal dichalcogenide nanoparticle material to be formed may include, but are not restricted to, WO₂; WS₂; WSe₂; WTe₂; MoO₂; MoS₂; MoSe₂; MoTe₂; MnO₂; NiO₂; NiSe₂; NiTe₂; VO₂; VS₂; VSe₂; TaS₂; TaSe₂; RuO₂; RhTe₂; PdTe₂; HfS₂; NbS₂; NbSe₂; NbTe₂; FeS₂; TiO₂; TiS₂; TiSe₂; and ZrS₂, and including doped materials and alloys thereof.

The nanoparticle shape is unrestricted and may be spherical, rod-shaped, disc-shaped, cube-shaped, hexagonal, tetrapod-shaped, etc. Reagents that have the ability to control the nanoparticle shape may be added to the reaction solution, for example a compound that may preferentially bind to a specific face and therefore inhibit or slow growth in a specific direction.

In one embodiment, the nanoparticles are QDs. QDs have widely been investigated for their unique optical, electronic and chemical properties, which originate from “quantum confinement effects”—when the dimensions of a semiconductor nanoparticle are reduced below twice the Bohr radius, the energy levels become quantized, giving rise to discrete energy levels. The band gap increases with decreasing particle size, leading to size-tunable optical, electronic and chemical properties, such as size-dependent photoluminescence. Moreover, it has been found that reducing the lateral dimensions of a 2D nanoflake into the quantum confinement regime may give rise to yet further unique properties, depending on both the lateral dimensions and the number of layers of the 2D nanoflake. In one embodiment, the lateral dimensions of the 2D nanoflakes may be in the quantum confinement regime, wherein the optical, electronic and chemical properties of the nanoparticles may be manipulated by changing their lateral dimensions. For example, metal chalcogenide monolayer nanoflakes of materials such as MoSe₂ and WSe₂ with lateral dimensions of approximately 10 nm or less may display properties such as size-tunable emission when excited. This can enable the electroluminescence maximum (ELₘₐₓ) or photoluminescence (PLₘₐₓ) of the 2D nanoflakes to be tuned by manipulating the lateral dimensions of the nanoparticles. As used herein, a “2D quantum dot” or “2D QD” refers to a semiconductor nanoparticle with lateral dimensions in the quantum confinement regime and a thickness between 1-5 monolayers. As used herein, a “single-layered quantum dot” or “single-layered QD” refers to a semiconductor nanoparticle with lateral dimensions in the quantum confinement regime and a thickness of a single monolayer. Compared with conventional QDs, 2D QDs have a much higher surface area-to-volume ratio, which decreases as the number of monolayers is decreased. The highest surface area-to-volume ratio is seen for single-layered QDs. This may lead to 2D QDs having very different surface chemistry from conventional QDs, which may be exploited for applications such as catalysis.

In one embodiment, the outermost layer of the nanoparticles is coated or “capped” with one or more organic ligands. Ligands may be used to impart solubility, allowing the nanoparticles to be solution processed. The ligand(s) may be provided by the solvent in which the nanoparticles are synthesised, through the use of a coordinating solvent or solvents, or may be added to the reaction solution. In one embodiment, an alkyl chalcogenide may act as both a chalcogenide precursor and a ligand.

The crystallographic phase of the nanoparticle material is preferably compatible with that of the molecular cluster. In some embodiments, the nanoparticle material and the molecular cluster share the same crystallographic phase. In alternative embodiments, the nanoparticle material and the molecular cluster have different crystallographic phases wherein the lattice spacing of the nanoparticle material is sufficiently close to that of the molecular cluster that deleterious lattice strain and/or relaxation (and concomitant defect generation) does not occur.

Further precursor(s) may be added to the reaction solution to form ternary, quaternary or higher order, or doped, nanoparticles.

After mixing the molecular cluster with the nanoparticle precursor(s), the reaction mixture is heated at an approximately steady rate until nanoparticle growth is initiated on the surface of the molecular cluster templates. At an appropriate temperature, further precursors may be added. In one embodiment, the nucleation stage is separated from the nanoparticle growth stage, enabling a high degree of control over the particle size. Nanoparticle growth may be controlled by controlling the temperature, for example, in the range of 25-350° C., and/or the concentration of the precursors present.

In one embodiment, the molecular cluster contains all of the elements to be incorporated into the subsequent nanoparticles. Suitable molecular clusters include, but are not restricted to: a transition metal-chalcogen cluster, for example, [Et₄N][Mo(SPh)(PPh₃)(mnt)₂].CH₂Cl₂ (mnt=1,2-dicyanoethyldithiolate); [PPh₄][MoO(SPh)₄]; (HNEt₃)[MoO(SPh—PhS)₂; [PPh₄][WO(SPh)₄; [Et₄N]₂[(edt)₂Mo₂S₂(μ-S)₂]; [Mo₄S₄(H₂O)₁₂]ⁿ⁺ (n=4, 5, 6); [Mo₃MS₄(H₂O)ₓ]⁴⁺ (x=10, 12; M=Cr, Ni); [Et₄N]₂[(edt)₂Mo₂S₄], [NH₄]₂[MoS₄]; [R₄H]₂[MoS₄] (R=alkyl), [W₃Se₇(S₂P(OEt)₂)₃]Br; [PPh₄]₂[W₃Se₉]; WS(S₂)(S₂CNEt₂)₂; [W₃Se₄(dmpe)₃Br₃]⁺ where dmpe=1,2-bis(dimethylphosphino)ethane; a metal thiophenolate; [Ni₃₄Se₂₂(PPh₃)₁₀]; Ti(S^{t}Bu)₄; [TiCl₄(HSR)₂] R=hexyl, cyclopentyl; CH₃C₅H₄)₄Ti₄S₈Oₓ (x=1, 2); [TiCl₄(Se(C₂H₅)₂)₂]; [(η5-C₅H₅)₂Ti(S^{t}Bu)₂] and [(η5-C₅H₅)₂Ti(SEt)₂].

In another embodiment, the cluster contains one of the elements to be incorporated into the subsequent nanoparticles. Suitable molecular clusters include, but are not restricted to: [R₃NR′]₄[M₁₀E₄(E′Ph)₁₆] where M=Cd or Zn; E, E′=S or Se; and R, R′=H, Me and/or Et, for example, [Et₃NH]₄[Cd₁₀S₄(SPh)]₁₆, [Et₃NH]₄[Zn₁₀S₄(SPh)]₁₆, [Et₃NH]₄[Cd₁₀S₄(SePh)]₁₆, or [Et₃NH]₄[Zn₁₀S₄(SePh)]₁₆; [Zn(OC(O)C(Me)N(OMe))₂].2H₂O; M(Se₂CNEt)₂ (M=Zn, Cd); cubane precursors of the type [Ga(S-i-Pr)₂(μ-S-i-Pr)]₂; [R₂Ga(SePⁱPr₂)₂N], (R=Me, Et); [(^{t}Bu)GaE] (E=S, Se; n=2, 4, 6, 7); [GaCl₃(ⁿBu₂E)] (E=Se, Te); [(GaCl₃)₂{ⁿBuE(CH₂)ₙEₙBu}] (E=Se, n=2; E=Te, n=3); [(R)Ga(μ₃-E)]₄ (R=CMe₃, CEtMe₂, and CEt₂Me; E=Se, Te); Ru₄Bi₂(CO)₁₂; Fe₄P₂(CO)₁₂; Fe₄N₂(CO)₁₂; and carbamate precursors of the type R₂ME₂CNR₂ (R=Me, Et, butyl, hexyl; E=S, Se).

In a further embodiment, the cluster contains none of the elements to be incorporated into the subsequent nanoparticles.

In one embodiment, the cluster is formed in situ from suitable precursors, for example a transition metal precursor and a chalcogen precursor during nanoparticle growth. Suitable metal precursors may include, but are not restricted to:
metal halides such as WClₙ (n=4-6), Mo₆Cl₁₂, MoCl₃, [MoCl₅]₂, NiCl₂, MnCl₂, VCl₃, TaCl₅, RuCl₃, RhCl₃, PdCl₂, HfCl₄, NbCl₅, FeCl₂, FeCl₃, TiCl₄, SrCl₂, SrCl₂.6H₂O, WO₂Cl₂, MoO₂Cl₂, WF₆, MoF₆, NiF₂, MnF₂, TaF₅, NbF₅, FeF₂, FeF₃, TiF₃, TiF₄, SrF₂, NiBr₂, MnBr₂, VBr₃, TaBr₅, RuBr₃.XH₂O, RhBr₃, PdBr₂, HfBr₄, NbBr₅, FeBr₂, FeBr₃, TiBr₄, SrBr₂, NiI₂, MnI₂, RuI₃, RhI₃, PdI₂ or TiI₄;
(NH₄)₆H₂W₁₂O₄₀ or (NH₄)₆H₂Mo₁₂O₄₀;
organometallic precursors such as metal carbonyl salts, for example, Mo(CO)₆, W(CO)₆, Ni(CO)₄, Mn₂(CO)₁₀, Ru₃(CO)₁₂, Fe₃(CO)₁₂ or Fe(CO)₅ and their alkyl and aryl derivatives;
acetates, for example, Ni(ac)₂.4H₂O, Mn(ac)₂.4H₂O, Rh₂(ac)₄, Pd₃(ac)₆, Pd(ac)₂, Fe(ac)₂ or Sr(ac)₂, where ac=OOCCH₃;
acetylacetonates, for example, Ni(acac)₂, Mn(acac)₂, V(acac)₃, Ru(acac)₃, Rh(acac)₃, Pd(acac)₂, Hf(acac)₄, Fe(acac)₂, Fe(acac)₃, Sr(acac)₂ or Sr(acac)₂.2H₂O, where acac=CH₃C(O)CHC(O)CH₃;
hexanoates, for example, Mo[OOCH(C₂H₅)C₄H]ₓ, Ni[OOCCH(C₂H₅)C₄H₉]₂, Mn[OOCCH(C₂H₅)C₄H₉]₂, Nb[OOCCH(C₂H₅)C₄H₉]₄, Fe[OOCCH(C₂H₅)C₄H₉]₃ or Sr[OOCCH(C₂H₅)C₄H₉]₂;
stearates, for example, Ni(st)₂ or Fe(st)₂, where st=O₂Cl₁₈H₃₅;
amine precursors, for example, complexes of the form [M(CO)ₙ(amine)₆₋ₙ];
metal alkyl precursors, for example, W(CH₃)₆, or
bis(ethylbenzene)molybdenum [(C₂H₅)_{y}C₆H_{6-y}]₂Mo (y=1-4).

Suitable chalcogen precursors include, but are not restricted to: an alcohol; an alkyl thiol or an alkyl selenol; a carboxylic acid; H₂S or H₂Se; an organo-chalcogen compound, for example thiourea or selenourea; inorganic precursors, for example Na₂S, Na₂Se or Na₂Te; phosphine chalcogenides, for example trioctylphosphine sulphide, trioctylphosphine selenide or trioctylphosphine telluride; octadecene sulphide, octadecene selenide or octadecene telluride; or elemental sulphur, selenium or tellurium.

The method of synthesis is scalable and may facilitate the formation of nanoparticles with uniform properties in large quantities.

For photoluminescence applications, it is known that growing one or more “shell” layers of a wider band gap semiconductor material with a small lattice mismatch on a semiconductor QD nanoparticle “core” may increase the photoluminescence quantum yield of the nanoparticle material by eliminating defects and dangling bonds located on the core surface. In one embodiment, one or more shell layers of a second material are grown epitaxially on the core nanoparticle material to form a core/shell nanoparticle structure. Examples of core/shell nanoparticles may include, but are not restricted to, MoSe₂/WS₂ or MoSe₂/MoS₂.

In a further embodiment, the as-synthesised nanoparticles may be cut to form, for example, 2D nanoflakes of TMDC material. As used herein, the “cutting” of a nanoparticle means the separation of the nanoparticle into two or more parts. The term is not intended to imply any restriction on the method of separation, and can include physical and chemical methods of separation. For example, Applicant's co-pending U.S. patent application Ser. No. 15/631,323 filed on Jun. 23, 2017, describes the chemical cutting of prefabricated nanoparticles.

In one embodiment, a core/shell nanoparticle may be cut to form a core/shell 2D nanoflake. As used herein, “core/shell 2D nanoflake” refers to a 2D nanoflake of a first material wherein at least one surface of the first material is at least partially covered by second material. In an alternative embodiment, core/shell 2D nanoflakes may be produced by the chemical cutting of prefabricated core nanoparticles, followed by the formation of one or more shell layers on core 2D nanoflakes.

### Description of the Preparative Procedure

The first step in preparing TMDC nanoparticles in an exemplary process according to the invention is the use of a molecular cluster as a template to seed the growth of the nanoparticles from transition metal and chalcogen source precursors. This is achieved by mixing small quantities of a cluster that is to be used as a template with a high boiling point solvent that can also be the capping agent, or an inert solvent with the addition of a capping agent compound. Further to this, a source of transition metal and chalcogen precursor are added in the form of two separate precursors, one containing the transition metal and the other containing the chalcogen, or in the form of a single-source precursor.

Further to this, other reagents that have the ability to control the shape of the nanoparticle grown may optionally be added to the reaction. These additives are in the form of a compound that may preferentially bind to a specific face (lattice plane) of the growing nanoparticle and thus inhibit or slow growth along that specific direction of the nanoparticle. Other element-source precursors may optionally be added to produce ternary, quaternary, higher order or doped nanoparticles.

Initially, the compounds of the reaction mixture are allowed to mix on a molecular level at a sufficiently low temperature that no significant particle growth will occur. The reaction mixture is then heated at a steady rate until particle growth is initiated on the surfaces of the molecular cluster templates. At an appropriate temperature after the initiation of particle growth, further quantities of metal and chalcogen precursors may be added to the reaction if needed so as to inhibit particles consuming one another by the process of Ostwald ripening. Further precursor addition may be in the form of batch addition, whereby solid precursors, liquids, solutions or gases are added over a period of time, or by continuous dropwise addition. Because of the complete separation of particle nucleation and growth, the method displays a high degree of control in terms of particle size, which may be controlled by the temperature of the reaction and the concentration of the precursors present. Once the desired particle size is reached, which may be established by UV and/or PL spectra of the reaction solution by, for example, an in situ probe or from aliquots of the reaction solution, the temperature may optionally be reduced, for example by circa 30-40° C., and the mixture left to “size-focus” for a period of time, for example between 10 minutes to 72 hours.

Further consecutive treatments of the as-formed nanoparticles to form core/shell or core/multishell nanoparticles may be undertaken. Core/shell nanoparticle preparation may be undertaken either before or after nanoparticle isolation, whereby the nanoparticles are isolated from the reaction and redissolved in a new (clean) capping agent as this may result in a better PL quantum yield. To form a shell of NY material, an N precursor and a Y precursor are added to the reaction mixture and may either be in the form of two separate precursors, one containing N and the other containing Y, or as a single-source precursor that contains both N and Y within a single molecule.

The process may be repeated with the appropriate element precursors until the desired core/multishell material is formed. The nanoparticle size and size distribution in an ensemble may be dependent on growth time, temperature, and concentrations of reactants in solution, with higher temperatures producing larger nanoparticles.

To form 2D nanoflakes, the as-formed nanoparticles (either prior to or after the growth of any shell layers) may be treated using a cutting procedure. For example, the nanoparticles may be cut into 2D nanoflakes by stirring the nanoparticles in a solution containing intercalating and exfoliating agents, or by refluxing the nanoparticles in a high boiling solvent.

### EXAMPLES

### Example 1

### Preparation of MoS₂ 2D Quantum Dots on a ZnS Molecular Cluster

Preparation of [Et₃NH]₄[Zn₁₀S₄(SPh)₁₆] Cluster

Anhydrous methanol (400 mL) was added to a 1-L flask containing Zn(NO₃)₂.6H₂O (210 g) and the solution was stirred until all the solid had dissolved. Benzenethiol (187 mL), trimethylamine (255 mL) and anhydrous methanol (400 mL) were mixed together in a 3-L three-necked round-bottom flask, under N₂. The methanolic solution of Zn(NO₃)₂.6H₂O was added to the flask via a cannula, over approximately two hours, under constant stirring, until all solid had dissolved. The clear solution was stored in a freezer for 16 hours, during which time a white solid crystallised. The solid, [Et₃NH]₂[Zn₄(SPh)₁₀], was filtered using a Buchner flask and funnel, washed twice with methanol, and dried under vacuum for 1 hour to remove excess solvent and obtain a dry white powder. The solid was weighted (258 g) and mixed with anhydrous acetonitrile (700 mL) in a 2-L flask under N₂, and the resulting solution was heated gently using a heat gun until all the solid had dissolved. Finely ground sulphur powder (2.65 g; half the molar amount of [Et₃NH]₂[Zn₄(SPh)₁₀]) was added and the resulting cloudy yellow solution was carefully stirred for approximately 10 minutes until all the solid had dissolved. The yellow solution was left undisturbed in a freezer over 16 hours, after which time a white solid had precipitated. The solution was filtered with a Buchner flask and funnel, and the solid was washed twice with acetonitrile. The solid was dried under vacuum for 5 hours to remove excess solvent and stored as a white powder under N₂.

Preparation of MoS₂ Nanoparticles

Trioctylphosphine oxide (7 g) and hexadecylamine (3 g) were degassed at 110° C. for 1 hour, in a three-necked round-bottom flask equipped with a condenser and thermocouple. [Et₃NH]₄[Zn₁₀S₄(SPh)₁₆] cluster (1 g) was added as a powder through a side port and the resulting solution was degassed at 110° C. for a further 30 minutes. The flask was then back-filled with N₂ and the temperature was ramped to 250° C.

Separately, a solution of Mo-octylamine complex was prepared by mixing Mo(CO)₆ (0.132 g) with dioctylamine (2 mL) and hexadecane (10 mL) at 160° C. and stirring for 30 minutes under N₂. The resulting reddish brown solution was cooled to 30° C. and injected dropwise at a rate of 5 mL/h into the reaction solution containing the cluster. The colour of the reaction solution gradually changed from pale yellow to black. After the injection was complete, the reaction solution was left to anneal at 250° C. for 30 minutes. After this time, a pre-degassed solution of dodecanethiol (1.5 mL) in hexadecane (2 mL) was injected dropwise at a rate of 3 mL/h. After the injection was complete, the reaction solution was left to anneal at 250° C. for 30 minutes. The reaction solution was cooled to 60° C. and methanol (40 mL) was added to precipitate the nanoparticles. The resulting suspension was centrifuged at 8,000 rpm for 5 minutes to isolate a black pellet. The pellet was dissolved in toluene. The nanoparticles were purified by four repetitive cycles of reprecipitation with methanol, centrifugation and dispersion in toluene.

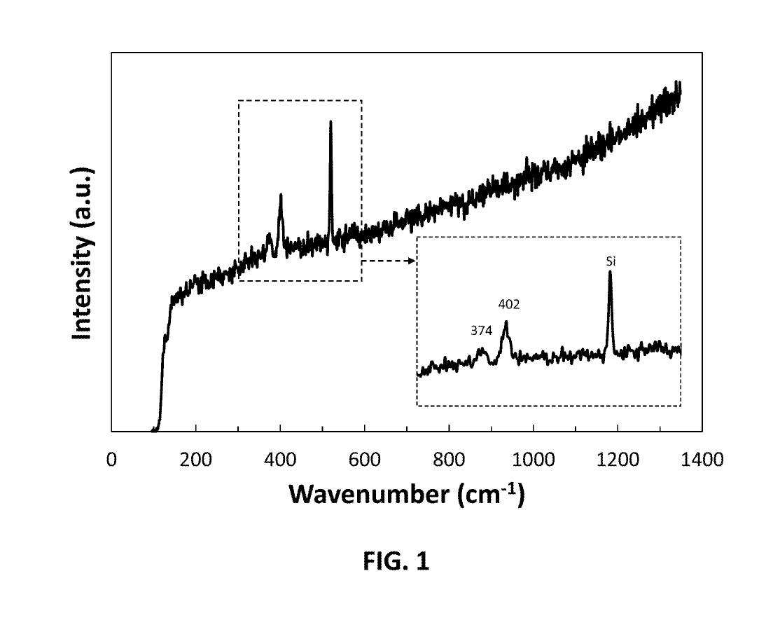

FIG. 1 shows the Raman spectrum of the nanoparticles, with bands at 374 cm⁻¹ and 402 cm⁻¹ that are characteristic of MoS₂.

Chemical Cutting of MoS₂ Nanoparticles via Intercalation and Exfoliation to form 2D Quantum Dots

The MoS₂ nanoparticles were dissolved in hexane (solution volume 25 mL). The solution was dispersed in propylamine (10 mL) and hexylamine (3 mL), then left stirring under N₂ for 4 days. The amines were removed under vacuum.

Acetonitrile (200 mL) was added, followed by stirring for 3 days. The acetonitrile was removed using a rotary evaporator. The residue was redispersed in acetonitrile and left in a vial with air in the head space.

### Example 2

### Preparation of MoS₂ 2D Quantum Dots on a ZnS Molecular Cluster

[Et₃NH]₄[Zn₁₀S₄(SPh)₁₆] cluster was prepared according to Example 1.

### Preparation of MoS₂ Nanoparticles

Trioctylphosphine oxide (7 g) and hexadecylamine (3 g) were degassed at 110° C. [Et₃NH]₄[Zn₁₀S₄(SPh)₁₆] cluster (1 g) was added and the resulting solution was degassed at 110° C. for a further 30 minutes. The flask was then back-filled with N₂ and the temperature was ramped to 250° C.

Separately, a solution of Mo-octylamine complex was prepared by mixing Mo(CO)₆ (0.264 g) with dioctylamine (4 mL) and hexadecane (6 mL) at 160° C. and stirring for 30 minutes under N₂. The resulting reddish brown solution was cooled to 30° C. and injected dropwise at a rate of 10 mL/h into the reaction solution containing the cluster. The colour of the reaction solution gradually changed from pale yellow to black. After the injection was complete, the reaction solution was left to anneal at 250° C. for 30 minutes. After this time, a pre-degassed solution of dodecanethiol (3 mL) in hexadecane (4 mL) was injected dropwise at a rate of 3 mL/h. After the injection was complete, the reaction solution was left to anneal at 250° C. for 1 hour. The reaction solution was cooled to 60° C. and isolated with methanol (20 mL) and acetone (20 mL) to precipitate the nanoparticles. The material was redissolved in hexane (10 mL) and reprecipitated with acetone (30 mL). The material was then reprecipitated from toluene with methanol, twice, before finally dispersing in hexane.

Chemical Cutting of MoS₂ Nanoparticles via Reflux to form 2D Quantum Dots

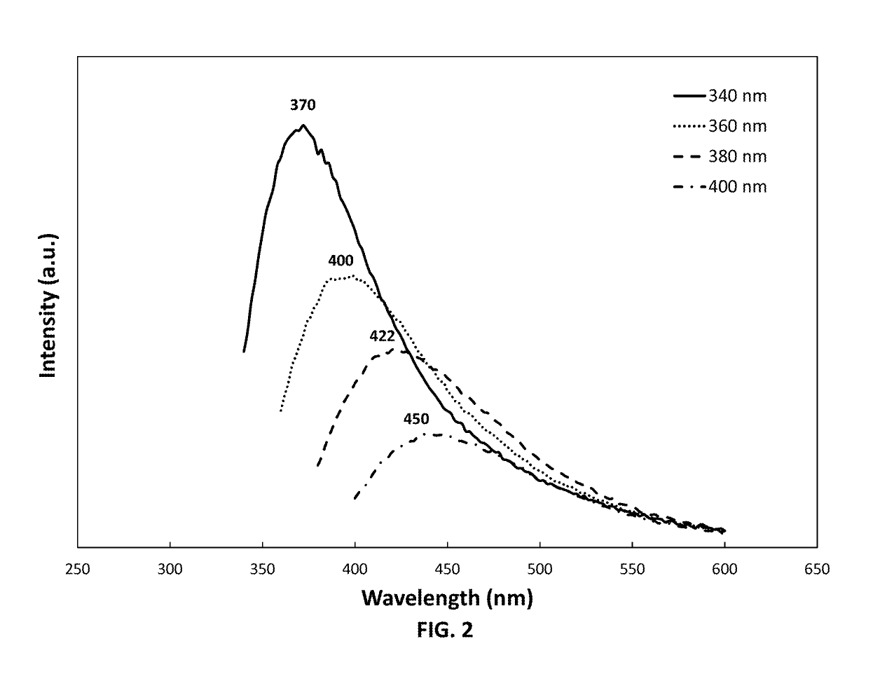

The MoS₂ nanoparticles in hexane were injected into degassed myristic acid (10 g). The hexane was removed and the solution was heated to reflux for 50 minutes, before cooling to approximately 80° C. Acetone (200 mL) was added, followed by centrifugation, and the solid was separated and discarded. The supernatant was removed under vacuum to leave a dry residue and acetonitrile (200 mL) was added, followed by centrifugation. The solid was separated. The supernatant was removed under vacuum and the residue redissolved in toluene. The photoluminescence (PL) spectrum (FIG. 2) shows excitation wavelength-dependent PL, with the narrowest and highest intensity emission at 370 nm resulting from excitation at 340 nm.

These and other advantages of the present invention will be apparent to those skilled in the art from the foregoing disclosure. Accordingly, it is to be recognized that changes or modifications may be made to the above-described embodiments without departing from the broad inventive concepts of the invention. It is to be understood that this invention is not limited to the particular embodiments described herein and that various changes and modifications may be made without departing from the scope of the present invention as literally and equivalently covered by the following claims.

What is claimed is:

1. A two-dimensional nanoflake comprising:
a molecular cluster compound; and
a core semiconductor material disposed on the molecular cluster compound.

2. The two-dimensional nanoflake of claim 1, wherein the core semiconductor material comprises an element of the transition metals and an element of Group 16 of the periodic table.

3. The two-dimensional nanoflake of claim 2, wherein the element of the transition metals is selected from the group consisting of Mo and W.

4. The two-dimensional nanoflake of claim 2, wherein the element of Group 16 comprises O, S, Se or Te.

5. The two-dimensional nanoflake of claim 1, wherein the two-dimensional nanoflake is a two-dimensional quantum dot.

6. The two-dimensional nanoflake of claim 1, wherein the two-dimensional nanoflake is a single-layered quantum dot.

7. The two-dimensional nanoflake of claim 1 further comprising a shell of a second semiconductor material disposed on the core semiconductor material.

8. The two-dimensional nanoflake of claim 1, wherein the core semiconductor material comprises one or more elements not in the molecular cluster compound.

9. The two-dimensional nanoflake of claim 1, wherein the molecular cluster compound is [R₃NR′]₄[M₁₀E₄(SPh)₁₆] where M=Cd or Zn; E and E′ are independently selected from S and Se; and R and R′ are independently selected from the group consisting of H, Me and Et.

10. The two-dimensional nanoflake of claim 1, wherein the two-dimensional nanoflake further comprises an outermost layer comprising a ligand.

11. The two-dimensional nanoflake of claim 10, wherein the ligand comprises an alkyl chalcogenide.

12. The two-dimensional nanoflake of claim 1, wherein the two-dimensional nanoflake emits light of a second wavelength when irradiated by light of a first wavelength.

13. A method of producing a two-dimensional nanoflake comprising:
converting a nanoparticle precursor composition to a nanoparticle, wherein said converting is effected in the presence of a molecular cluster, under conditions permitting seeding and growth of the nanoparticle; and
converting the nanoparticle to the two-dimensional nanoflake using a cutting procedure.

14. The method of claim 13, wherein the nanoparticle precursor composition comprises:
a first precursor species containing a first ion to be incorporated into the nanoparticle; and
a second precursor species containing a second ion to be incorporated into the nanoparticle.

15. The method of claim 13, wherein the nanoparticle precursor composition comprises a single-source precursor.

16. The method of claim 13, wherein the two-dimensional nanoflake is a two-dimensional quantum dot.

17. The method of claim 13, wherein the two-dimensional nanoflake is a single-layered quantum dot.

18. The method of claim 13, wherein the cutting procedure comprises refluxing the nanoparticle in a solvent.

19. The method of claim 18, wherein the solvent comprises myristic acid.

20. The method of claim 13, wherein the cutting procedure comprises intercalation and exfoliation.
